(19) United States
(12) Patent Application Publication
(10) Pub. No.: US 2026/0018205 A1
(43) Pub. Date: Jan. 15, 2026

(54) MEMORY DEVICE

(71) Applicant: SAMSUNG ELECTRONICS CO., LTD., Suwon-si (KR)

(72) Inventors: Sangyun KIM, Suwon-si (KR); Kyuchang Kang, Suwon-si (KR); Incheol Nam, Suwon-si (KR); Jaejoon Song, Suwon-si (KR); Hyunchul Yoon, Suwon-si (KR)

(73) Assignee: SAMSUNG ELECTRONICS CO., LTD., Suwon-si (KR)

(21) Appl. No.: 19/022,363

(22) Filed: Jan. 15, 2025

(30) Foreign Application Priority Data
Jul. 15, 2024 (KR) 10-2024-0092815

(51) Int. Cl. G11C 11/4091; G11C 5/06; G11C 11/406; H10B 12/00

(52) U.S. Cl. CPC G11C 11/4091; G11C 5/063; G11C 11/406; H10B 12/315; H10B 12/482; H10B 12/488

(57) ABSTRACT

A memory device includes: memory cells connected to wordlines and local bitlines, each including a cell transistor and a cell capacitor. The cell transistor includes a first impurity region connected to a local bitline, a second impurity region connected to a cell capacitor, a body region between first and second impurity regions, and a gate structure connected to the wordline. The memory device includes a global bitline; multiplexers configured to selectively connect the local bitlines to the global bitline or a precharge power line; a bitline sense amplifier connected to the global bitline; and a body refresh control circuit configured to control the multiplexers to connect at least one target local bitline to the precharge power line, and control a voltage level of the precharge power line connected to the at least one target local bitline to a first level lower than a voltage level of the body region.

### CROSS-REFERENCE TO RELATED APPLICATION

This application claims priority to Korean Patent Application No. 10-2024-0092815, filed on Jul. 15, 2024, in the Korean Intellectual Property Office, the disclosure of which is incorporated herein by reference in its entirety.

### BACKGROUND

The present disclosure relates to a memory device.

A memory device may include a transistor. For example, in a memory device, such as a dynamic random access memory (DRAM), a memory cell may include a cell transistor. To improve integration density, resistance, and driving capability of a transistor, a transistor such as a vertical channel transistor (VCT) and a gate all around (GAA) in which a channel has an increased width have been suggested.

### SUMMARY

One or more example embodiments provide a memory device which may perform a body refresh operation to eliminate a floating body effect of a cell transistor.

An example embodiment of the present disclosure is to provide a memory device which may improve a speed of a body refresh operation and may perform a body refresh operation simultaneously with a data refresh operation.

According to an aspect of an example embodiment a memory device includes: a plurality of wordlines; a plurality of local bitlines; a plurality of memory cells connected to the plurality of wordlines and the plurality of local bitlines, wherein a first memory cell of the plurality of memory cells is connected to a wordline among the plurality of wordlines and a local bitline among the plurality of local bitlines, wherein the first memory cell includes a cell transistor and a cell capacitor, and wherein the cell transistor includes a first impurity region connected to the local bitline, a second impurity region connected to the cell capacitor, a body region between the first impurity region and the second impurity region, and a gate structure connected to the wordline on a surface of the body region; a global bitline; a plurality of multiplexers including a first multiplexer, the first multiplexer configured to selectively connect the local bitline to the global bitline or to a precharge power line; a bitline sense amplifier connected to the global bitline; and a body refresh control circuit configured to control a body refresh operation of controlling the plurality of multiplexers to connect at least one target local bitline among the plurality of local bitlines to the precharge power line, and control a voltage level of the precharge power line connected to the at least one target local bitline to a first level lower than a voltage level of the body region.

According to another aspect of an example embodiment a memory device, includes: a plurality of first wordlines; a plurality of second wordlines; a plurality of local bitlines; a plurality of complementary local bitlines; a plurality of first memory cells connected to the plurality of first wordlines and the plurality of local bitlines; a plurality of second memory cells connected to the plurality of second wordlines and the plurality of complementary local bitlines; a global bitline; a complementary global bitline; a plurality of first multiplexers configured to selectively connect each of the plurality of local bitlines to the global bitline or a precharge power line; a plurality of second multiplexers configured to selectively connect each of the plurality of complementary local bitlines to the complementary global bitline or the precharge power line; a bitline sense amplifier connected to the global bitline and the complementary global bitline; and a body refresh control circuit configured to: control the global bitline and the complementary global bitline to be precharged, and the plurality of local bitlines and the plurality of complementary local bitlines to be connected to the precharge power line, in a first period; control at least one complementary target local bitline selected from among the plurality of complementary local bitlines to be connected to the complementary global bitline, in a second period subsequent to the first period; control at least one target local bitline selected from among the plurality of local bitlines to be connected to the global bitline, in a third period subsequent the second period; and control a body refresh operation in which the bitline sense amplifier senses and amplifies a difference in voltage levels between the global bitline and the complementary global bitline in the second period and the third period.

According to another aspect of an example embodiment, a memory device, includes: a plurality of memory cell blocks, each of the plurality of memory cell blocks including a plurality of memory cells connected to a plurality of wordlines and a plurality of local bitlines; a plurality of global bitlines, each of the plurality of global bitlines corresponding to two or more local bitlines among the plurality of local bitlines; a plurality of multiplexers configured to selectively connect each of the plurality of local bitlines to a corresponding global bitline or a precharge power line; a plurality of bitline sense amplifiers, each of the plurality of bitline sense amplifiers connected to two global bitlines among the plurality of global bitlines, and configured to sense and amplify a difference in voltage levels between the two global bitlines; and a body refresh control circuit configured to control the plurality of multiplexers to connect a plurality of first local bitlines provided in at least one memory cell block among the plurality of memory cell blocks to the precharge power line, and to control perform a body refresh operation including lowering a voltage level of the precharge power line.

### BRIEF DESCRIPTION OF DRAWINGS

The above and other aspects, features, and advantages will be more apparent from the following description of example embodiments, taken in combination with the accompanying drawings, in which:

FIGS. 1A and 1B are diagrams illustrating a structure of a memory cell according to an example embodiment;

FIGS. 2A and 2B are diagrams illustrating voltage characteristics of a cell transistor according to an example embodiment;

FIG. 3 is a block diagram illustrating a memory system including a memory device according to an example embodiment;

FIG. 4 is a block diagram illustrating a memory device according to an example embodiment;

FIG. 5 is a perspective diagram illustrating a memory cell array structure according to an example embodiment;

FIG. 6 is a diagram illustrating a structure of a memory cell array according to an example embodiment;

FIG. 7 is a circuit diagram illustrating a memory device according to an example embodiment;

FIG. 8 is a diagram illustrating a body refresh circuit according to an example embodiment;

FIG. 9 is a signal diagram illustrating a body refresh operation according to an example embodiment;

FIG. 10 is a diagram illustrating a memory cell array according to an example embodiment;

FIG. 11 is a circuit diagram illustrating a body refresh circuit according to an example embodiment;

FIG. 12 is a diagram illustrating a bitline sense amplifier circuit according to an example embodiment;

FIG. 13 is a signal diagram illustrating a body refresh operation according to an example embodiment;

FIG. 14 is a circuit diagram illustrating a memory device according to an example embodiment; and

FIG. 15 is a diagram illustrating a memory cell array according to an example embodiment.

### DETAILED DESCRIPTION

Hereinafter, example embodiments will be described with reference to the accompanying drawings. Each example embodiment provided in the following description is not excluded from being associated with one or more features of another example or another example embodiment also provided herein or not provided herein but consistent with the present disclosure. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

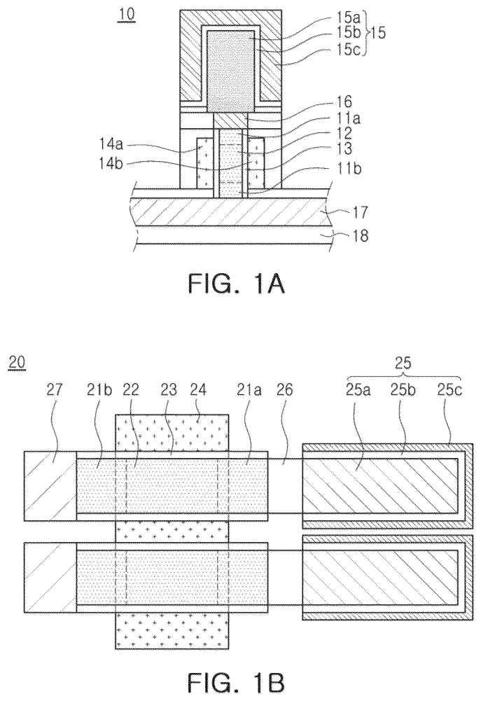

FIGS. 1A and 1B are diagrams illustrating a structure of a memory cell according to an example embodiment.

Referring to FIG. 1A, a memory cell 10 may include a cell transistor, a cell capacitor 15, and a cell contact 16. The cell transistor may include a first impurity region 11a, a second impurity region 11b, a body (channel) region 12, a gate insulating film 13, and gate electrodes 14a and 14b. The first impurity region 11a may be electrically connected to the cell capacitor 15 through the cell contact 16. The second impurity region 11b may be electrically connected to a bitline 17. In an example embodiment, the bitline 17 may be formed in the substrate 18.

The cell capacitor 15 may include a first electrode 15a connected to the first impurity region 11a, a second electrode 15c connected to a power voltage, and a dielectric layer 15b between the first electrode 15a and the second electrode 15c. For example, the power voltage may be a voltage having a ground level VSS.

To increase integration density of the memory cell 10 and to improve characteristics of the memory cell 10, the cell transistor may have a channel structure formed in a direction perpendicular to the substrate. That is, the cell transistor may be a vertical channel transistor (VCT). By doping upper and lower portions of the channel structure with impurities, a first impurity region 11a and a second impurity region 11b may be formed, and a body region 12 may be disposed between the first impurity region 11a and the second impurity region 11b. For example, the first impurity region 11a and the second impurity region 11b may be doped with N-type impurities, and the body region 12 may have P-type impurities.

The gate electrodes 14a and 14b may be formed on sidewalls of the channel structure. When voltage is applied to the gate electrodes 14a and 14b, a channel may be formed on a sidewall of the body region 12. Because a width of the channel may increase due to a channel structure formed vertically, memory cells may be integrated on the substrate and characteristics of the cell transistor may be improved.

When a channel is formed on a surface of the body region 12, the body in the channel may not have an electrical path directly connected to the substrate 18. That is, a voltage level of the body may not be fixed by the reference voltage, but may float. While the cell transistor operates, holes in the first impurity region 11a and the second impurity region 11b may be dispersed into the body. The holes dispersed into the body may be accumulated in the body region 12. Because the body floats, the holes may not escape through the substrate 18, and may increase a voltage level of the body.

Referring to FIG. 1B, the memory cell 20 may include a cell transistor, a cell capacitor 25, and a cell contact 26. The cell transistor may include a first impurity region 21a, a second impurity region 21b, a body region 22, a gate insulating film 23, and a gate electrode 24. The first impurity region 21a may be electrically connected to the cell capacitor 25 through the cell contact 26, and the second impurity region 21b may be electrically connected to the bitline 27. The cell capacitor 25 may include a first electrode 25a, a dielectric layer 25b, and a second electrode 25c.

To increase integration density of the memory cell 20 and to improve characteristics of the memory cell 20, the cell transistor may have a channel structure surrounded by the gate electrode 24. For example, the cell transistor may have a gate all around (GAA) structure. Both ends of the channel structure may be doped with impurities such that a first impurity region 21a and a second impurity region 21b may be formed. The entire surface of the body region 22 between the first impurity region 21a and the second impurity region 21b may be surrounded by the gate electrode 24. When a voltage is applied to the gate electrode 24, a channel may be formed on the entire surface of the body region 22. A width of the channel may be increased, and memory cells may be integrated on the substrate and characteristics of the cell transistor may be improved.

As in FIG. 1A, when a channel is formed in the body region 22, the body in the channel may electrically float. During transistor operation, holes dispersed into the body may not escape and may accumulate in the body region 22.

During operation of the memory cells described with reference to FIGS. 1A and 1B, characteristics of the memory cells may be deteriorated due to holes accumulated in the body region.

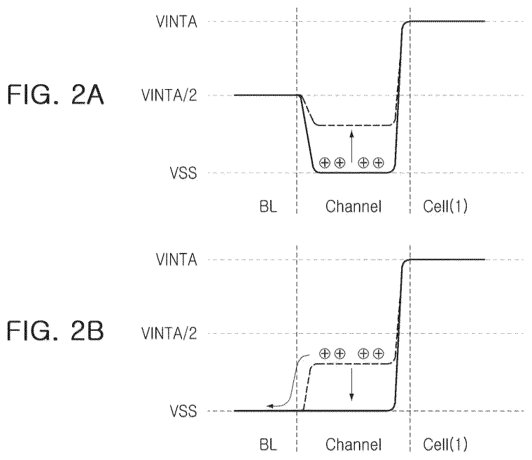

FIGS. 2A and 2B are diagrams illustrating voltage characteristics of a cell transistor according to an example embodiment.

FIG. 2A is a diagram illustrating voltage characteristics of a cell transistor due to normal operation of a memory cell.

FIG. 2A illustrates voltage levels of a bitline (BL), a body region (Channel), and a memory cell (Cell(1)) in a state in which data “1” is stored in a memory cell and a bitline BL is precharged as an example. The memory cell may have a first power voltage level, for example, the same level as a level of the internal power voltage VINTA supplied to the memory cell, and the bitline may have a precharge voltage level. For example, the precharge voltage level may have an intermediate level VINTA/2 between the first power voltage level and a second power voltage level lower than the first power voltage level. The second power voltage level may be a level of the ground voltage VSS.

When holes accumulate in the body region due to a normal operation of the memory cell, for example, a read operation and a write operation, the voltage level of the body region may gradually increase from the second power voltage level. As the voltage level of the body region increases, a threshold voltage may be lowered, and leakage current may occur, such that electric charge stored in the memory cell may be lost. Accordingly, the dynamic refresh characteristic, which indicates the extent to which the memory cell maintains the ability to retain electric charge, may be degraded.

A body refresh operation may be performed to restore characteristics of the memory cells by removing holes accumulated in the body region.

FIG. 2B is a diagram illustrating voltage level characteristics of a cell transistor after a body refresh operation is performed on the memory cell.

When the voltage level of the bitline is lowered than the voltage level of the body region, a forward bias may be formed between the P-type body region and the N-type impurity region connected to the bitline. For example, when the voltage level of the bitline is lowered to the second power voltage level, holes accumulated in the body region may be discharged through the bitline. When the holes are discharged, the threshold voltage may increase due to the lower voltage level of the body region, and the dynamic refresh characteristics of the memory cell may be restored.

An operation of lowering the voltage level of the bitline to lower the voltage level of the body region may be referred to as a body refresh operation. The body refresh operation may be distinguished from a data refresh operation of recovering the amount of electric charge stored in the memory cell based on data stored in the memory cell.

According to an example embodiment, a memory device including memory cells may have layered bitlines to reduce load capacitance. The memory device may efficiently perform a body refresh operation by using the layered structure of bitlines.

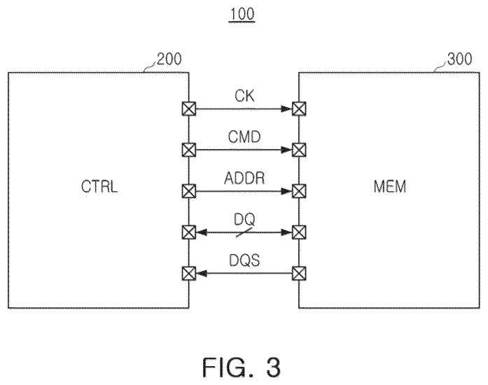

Hereinafter, a memory device according to an example embodiment will be described in greater detail with reference to FIGS. 3 to 15.

FIG. 3 is a block diagram illustrating a memory system including a memory device according to an example embodiment.

Referring to FIG. 3, a memory system 100 may include a memory controller 200 and a memory device 300.

The memory system 100 may be implemented to be included in a personal computer (PC) or a mobile electronic device. The mobile electronic device may be implemented as a laptop computer, a mobile phone, a smart phone, a tablet PC, a personal digital assistant (PDA), an enterprise digital assistant (EDA), a digital still camera, a digital video camera, a portable multimedia player (PMP), a personal navigation device (PND) or a portable navigation device, a handheld game console, a mobile internet device (MID), a wearable computer, an internet of things (IoT) device, an internet of everything (IoE) device, or a drone.

The memory controller 200 may be implemented as an integrated circuit, a system on chip (SoC), an application processor (AP), a mobile AP, a chipset, or a collection of chips. The memory controller 200 may include a random access memory (RAM), a central processing unit (CPU), a graphics processing unit (GPU), a neural processing unit (NPU), or a modem. In an example embodiment, the memory controller 200 may perform functions of a modem and an AP.

The memory device 300 may be implemented as a volatile memory device. The volatile memory device may be implemented as a random access memory (RAM), a dynamic RAM (DRAM), a static RAM (SRAM), or a low power double data rate (LPDDR) DRAM. In an example embodiment, the memory device 300 may include memory cells including cell transistors of a VCT or GAA structure. However, the structure of the memory cells included in the memory device 300 is not limited thereto.

The memory controller 200 may control the memory device 300 to read data stored in the memory device 300 or to write data in the memory device 300. The memory controller 200 may control a write operation for the memory device 300 by providing a command signal CMD and an address signal ADDR to the memory device 300 in synchronization with a control clock signal CK. The memory controller 200 may control a read operation for the memory device 300 by providing a command signal CMD and an address signal ADDR to the memory device 300 in synchronization with a control clock signal CK.

In an example embodiment, the memory controller 200 may provide a refresh command to the memory device 300. The memory device 300 may perform a data refresh operation and a body refresh operation in response to the refresh command of the memory controller 200.

The data signal DQ may be transmitted and received between the memory controller 200 and the memory device 300 in synchronization with a data strobe signal DQS. For example, during a write operation, the memory controller 200 may provide a data strobe signal DQS together with a data signal DQ to the memory device 300, and the memory device 300 may sample the data signal DQ using the data strobe signal DQS. During a read operation, the memory device 300 may provide a data strobe signal DQS together with the data signal DQ to the memory controller 200, and the memory controller 200 may sample the data signal DQ using the data strobe signal DQS.

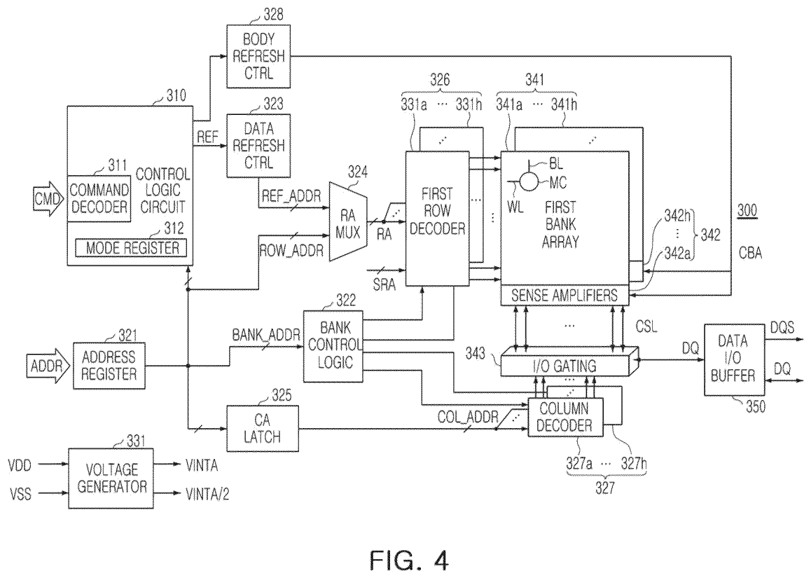

FIG. 4 is a block diagram illustrating a memory device according to an example embodiment.

Referring to FIG. 4, the memory device 300 may include a control logic circuit 310, an address register 321, a bank control logic (i.e., bank control circuit) 322, a data refresh control circuit 323, a row address multiplexer 324, a column address latch 325, a row decoder 326, a column decoder 327, a body refresh control circuit 328, a voltage generator (i.e., a power voltage generator) 331, a memory cell array 341, a sense amplifier 342, an input/output gate circuit 343 and a data input/output buffer 350.

The memory cell array 341 may include a plurality of memory cell arrays 341a-341h. Also, a plurality of row decoders 326 (326a-326h), a plurality of column decoders 327: 327a-327h, and a plurality of sense amplifiers 342 (342a-342h) may be connected to a plurality of memory cell arrays 341a-341h, respectively.

A plurality of memory cell arrays 341a-341h, a plurality of sense amplifiers 342a-342h, a plurality of column decoders 327a-327h, and a plurality of row decoders 326a-326h may be included in a plurality of banks. Each of the plurality of memory cell arrays 341a-341h may include a plurality of wordlines WL, a plurality of bitlines BL, and a plurality of memory cells MC formed at points at which the wordlines WL and the bitlines BL intersect.

The address register 321 may receive an address ADDR including a bank address BANK_ADDR, a row address ROW_ADDR and a column address COL_ADDR from the memory controller 200 described with reference to FIG. 3. The address register 321 may provide the received bank address BANK_ADDR to the bank control logic 322, the received row address ROW_ADDR to the row address multiplexer 324, and the received column address COL_ADDR to the column address latch 325.

The bank control logic 322 may generate bank control signals in response to the bank address BANK_ADDR. In response to the bank control signals, a row decoder corresponding to a bank address BANK_ADDR among a plurality of row decoders 324a-324h may be activated, and a column decoder corresponding to the bank address BANK_ADDR among the plurality of column decoders 327a-327h may be activated.

The data refresh control circuit 323 may increase or decrease the refresh row address REF_ADDR under control of the control logic circuit 310 in sequence. As a first example, the control logic circuit 310 may perform an auto-refresh operation of controlling the data refresh control circuit 323 based on a refresh command received from the memory controller 200. For a second example, the control logic circuit 310 may perform a self-refresh operation of controlling the data refresh control circuit 323 based on an internal timer.

When the auto-refresh operation is performed and the self-refresh operation is performed, the read and write operations by the memory controller may not be performed. For example, the memory controller may transmit a refresh command when the read and write operations are not performed. The control logic circuit 310 may start the self-refresh operation at a time at which the read and write commands are not received.

The row address multiplexer 324 may receive the row address ROW_ADDR from the address register 321 and the refresh row address REF_ADDR from the refresh counter 323. The row address multiplexer 324 may selectively output the row address ROW_ADDR or the refresh row address REF_ADDR as the row address RA. The row address RA output by the row address multiplexer 324 may be applied to each of the plurality of row decoders 326a-326h.

Among the plurality of row decoders 326a-326h, a row decoder activated by the bank control logic 322 may decode the row address RA output by the row address multiplexer 324 and may activate the wordline corresponding to the row address. For example, the activated row decoder may apply a wordline driving voltage to the wordline corresponding to the row address.

The column address latch 325 may receive the column address COL_ADDR from the address register 321 and may temporarily store the received column address COL_ADDR. Also, the column address latch 325 may incrementally increase the received column address COL_ADDR in a burst mode. The column address latch 325 may apply the temporarily stored or incrementally increased column address COL_ADDR to the plurality of column decoders 327a-327h, respectively.

Among the plurality of column decoders 327a-327h, a column decoder activated by the bank control logic 322 may activate a sense amplifier corresponding to the bank address BANK_ADDR and the column address COL_ADDR through a corresponding input/output gating circuit 343.

The body refresh control circuit 328 may control the body refresh operation in response to control of the control logic circuit 310. The body refresh control circuit 328 may determine a region in which a body refresh operation is to be performed among the plurality of memory cell arrays 341a-341h, and may provide a signal indicating the region to each of the sense amplifiers 342a-342h.

For example, to address increased integration density of memory cells, the bitline BL of the plurality of memory cell arrays 341a-341h may be hierarchized into global bitlines and local bitlines. Each of the plurality of memory cell arrays 341a-341h may include a plurality of memory cell blocks including a plurality of memory cells connected to a plurality of local bitlines and a plurality of wordlines. The body refresh control circuit 328 may determine a memory cell block in which a body refresh operation is to be performed among the plurality of memory cell blocks, and may provide a memory cell block address CBA to each of the sense amplifiers 342a-342h.

A sense amplifier activated by bank control logic 322 among the plurality of sense amplifiers 342a-342h may perform a body refresh operation to decrease voltage levels of local bitlines corresponding to the region.

An input/output gating circuit 343 may include circuits for gating input/output data, input data mask logic, read-out data latches for storing data output by a plurality of memory cell arrays 341a-341h, and write drivers for writing data in the plurality of memory cell arrays 341a-341h. The write drivers may be connected to the sense amplifiers 342a-342h through the column select lines CSL, respectively. The column select lines CSL may correspond to global bitlines of the memory cell arrays 341a-341h, respectively. The column decoders 327a-327h may select the column select lines CSL in response to the column address COL_ADDR.

A data signal DQ read-out from one bank array of the plurality of memory cell arrays 341a-341h may be sensed by a sense amplifier corresponding to the bank array and may be stored in the read-out data latches.

The data input/output buffer 350 may provide the data signal DQ to a bank array of the plurality of memory cell arrays 341a-341h in a write operation, and may output the data signal DQ output by one of the plurality of memory cell arrays 341a-341h to the memory controller 200 in a read operation.

The voltage generator 331 may generate voltages required for operation of the memory device 300. For example, the voltage generator 331 may receive a first external power voltage VDD and a second external power voltage VSS having a level lower than a level of the first external power voltage VDD from an external entity. The voltage generator 331 may generate an internal power voltage VINTA and a precharge power voltage VINTA/2, which may be input to the memory cell arrays 341a-341h.

The control logic circuit 310 may control operation of the memory device 300. For example, the control logic circuit 310 may generate control signals to allow the memory device 300 to perform a write operation or a read-out operation. The control logic circuit 310 may include a command decoder 311 for decoding a command CMD received from the memory controller 200 and a mode register 312 for determining an operation mode of the memory device 300.

For example, the command decoder 311 may decode a write enable signal, a row address strobe signal, a column address strobe signal, and a chip select signal, and may generate the control signals corresponding to the command CMD.

The control logic circuit 310 may control the data refresh operation of the data refresh circuit 323 and the body refresh operation of the body refresh circuit 328. For example, the control logic circuit 310 may provide a refresh control signal REF to the data refresh circuit 323 or the body refresh circuit 328 in response to an external command or based on an internal timer.

The control logic circuit 310 may perform the body refresh operation during an auto-refresh period or a self-refresh period. While the body refresh operation is performed, read and write operations may not be performed, and data stored in the memory cells may be protected.

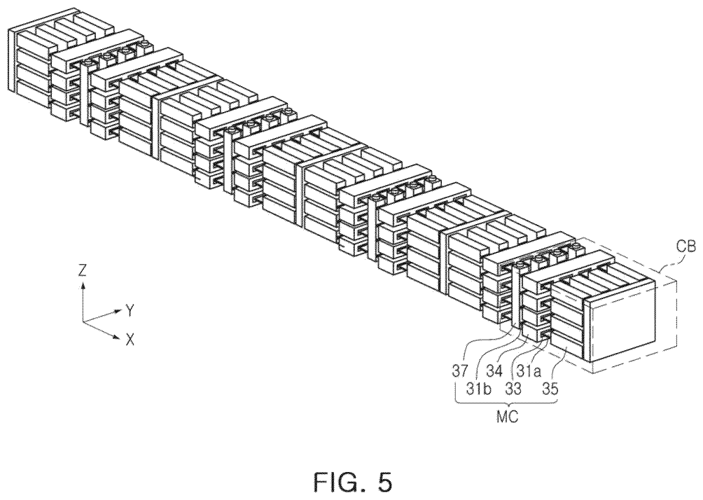

Hereinafter, a structure of a memory cell array having layered bitlines will be described with reference to FIGS. 5 to 7.

FIG. 5 is a perspective diagram illustrating a memory cell array structure according to an example embodiment.

Referring to FIG. 5, the memory cell array structure MCAS may include a plurality of memory cells MC arranged in a first direction X and a second direction Y parallel to an upper surface of a substrate of the memory device, and stacked in a third direction Z perpendicular to the upper surface of the substrate. Each of the memory cells MC may have a structure similar to the memory cell described with reference to FIG. 1B. A DRAM device in which a plurality of memory cells MC are stacked in the third direction Z may be referred to as a vertical stack (VS)-DRAM device.

The memory cell MC may include a cell transistor and a cell capacitor 35. The cell transistor may include a channel structure, a gate insulating layer 33, and a gate electrode 34. In the example in FIG. 5, a first impurity region 31a and a second impurity region 31b on both ends of the channel structure are illustrated. A body region of which an entire surface is surrounded by the gate electrode 34 may be included between the first impurity region 31a and the second impurity region 31b of the channel structure. The first impurity region 31a may be electrically connected to the cell capacitor 36, and the second impurity region 31b may be electrically connected to the bitline 37.

The gate electrode 34 may extend in the second direction Y, and channel structures including the first impurity region 31a, the second impurity region 31b, and the body region may be arranged in the second direction Y while being surrounded by the gate electrode 34. The gate electrode 34 may provide a wordline.

The bitline 37 may extend in the third direction Z. The memory cells MC stacked in the third direction Z may be connected to the bitline 37 extending in the third direction Z.

The bitlines 37 extending in the third direction Z, the gate electrodes 34 extending in the second direction Y, and the plurality of memory cells MC connected to the bitlines 37 and the gate electrodes 34 may be included in a memory cell block CB.

The memory cell array structure MCAS may include a plurality of memory cell blocks CB arranged in at least the first direction X. In an example embodiment, the memory cell array structure MCAS may include memory cell blocks CB arranged in the first direction X and the second direction Y.

Core circuits, such as sense amplifiers included in the memory bank, may be stacked with the memory cell array structure MCAS in the third direction Z. For example, the memory device may have a cell on periphery (CoP) structure or a periphery on cell (PoC) structure.

Because the memory cells MC are stacked in the third direction Z, the bitlines 37 may be highly integrated in the first direction X and the second direction Y. When bitline sense amplifiers for the bitlines 37, respectively, are disposed in the memory device, the region occupied by the bitline sense amplifiers may be larger than the region occupied by the memory cell array structure MCAS.

To reduce the area occupied by the bitline sense amplifiers in the memory device, the bitlines may be hierarchized. For example, the bitlines 37 arranged in the first direction X among the plurality of bitlines 37 may be connected to a global bitline, and the global bitline may be connected to the bitline sense amplifier. The bitline sense amplifier may sense and amplify data of a plurality of local bitlines connected to the global bitline. To distinguish the bitlines 37 from global bitlines, the bitlines 37 may be referred to as local bitlines.

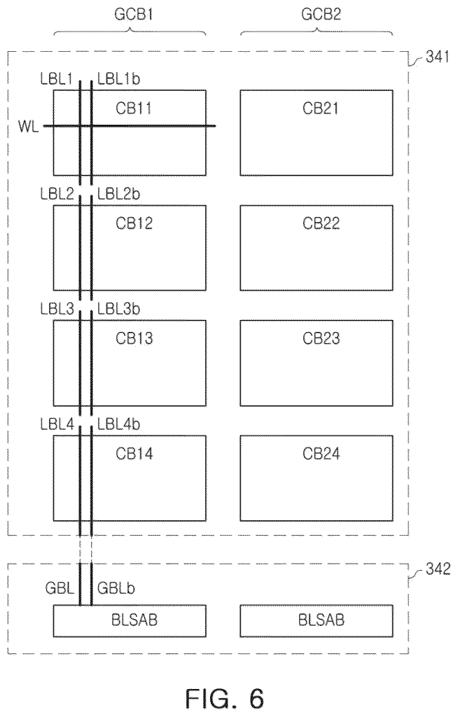

FIG. 6 is a diagram illustrating a structure of a memory cell array according to an example embodiment.

FIG. 6 illustrates a memory cell array 341 and a sense amplifier 342 described with reference to FIG. 4.

The memory cell array 341 may include a plurality of memory cell blocks CB (CB11, CB12, CB13, CB14, CB21, CB22, CB23, and CB24). Each of the memory cell blocks CB may include a plurality of wordlines WL, a plurality of local bitlines LBL, and a plurality of memory cells connected to the wordlines WL and the local bitlines LBL. Each of the memory cell blocks CB in FIG. 6 may correspond to the memory cell block CB described with reference to FIG. 5.

Local bitlines LBL (LBL1, LBL2, LBL3, LBL4) included in different memory cell blocks may be connected to the global bitline GBL, and the global bitline GBL may be connected to a bitline sense amplifier. For example, the global bitline may extend in the first direction X from an upper portion of the memory cell array structure MCAS as described with reference to FIG. 5, and the local bitlines included in a plurality of memory cell blocks arranged in the first direction X may be connected to the global bitline. Each of the local bitlines LBL (LBL1, LBL2, LBL3, LBL4) may be paired with a complementary local bitline (LBL1b, LBL2b, LBL3b, LBL4b),

Memory cell blocks having memory cells connected to the global bitline may be referred to as a global cell block. In the example in FIG. 6, the memory cell array 341 may include two global cell blocks GCB1, GCB2.

One bitline sense amplifier may be connected to global bitline pair GBL and GBLb. The bitline sense amplifier may read data stored in a memory cell or may write data in a memory cell by sensing and amplifying a difference in voltage levels between the global bitline pair GBL and GBLb. The global bitline pair may include a global bitline GBL and a complemental global bitline GBLb. The global bitline GBL may be connected to first to fourth local bitlines LBL1, LBL2, LBL3, and LBL4 included in a plurality of memory cell blocks CB11, CB12, CB13, and CB14. The complementary global bitline GBLb may be connected to first to fourth complementary local bitlines LBLb1, LBLb2, LBLb3, and LBLb4 included in a plurality of memory cell blocks CB11, CB12, CB13, and CB14.

The sense amplifier 342 may include a plurality of bitline sense amplifiers, each connected to a global bitline pair. In the example in FIG. 6, bitline sense amplifier blocks BLSAB corresponding to each of two global cell blocks GCB1 and GCB2 are illustrated. Each of the bitline sense amplifier blocks BLSAB may include a plurality of bitline sense amplifiers.

When the plurality of local bitlines LBLs are connected to the global bitline GBL, loading capacitance of the global bitline GBL may increase due to memory cells connected to the plurality of local bitlines LBLs. To reduce loading capacitance, each of the plurality of local bitlines LBLs may be connected to the global bitline GBL through multiplexer circuits for connecting a local bitline LBL selected from among the plurality of local bitlines LBLs to the global bitline GBL.

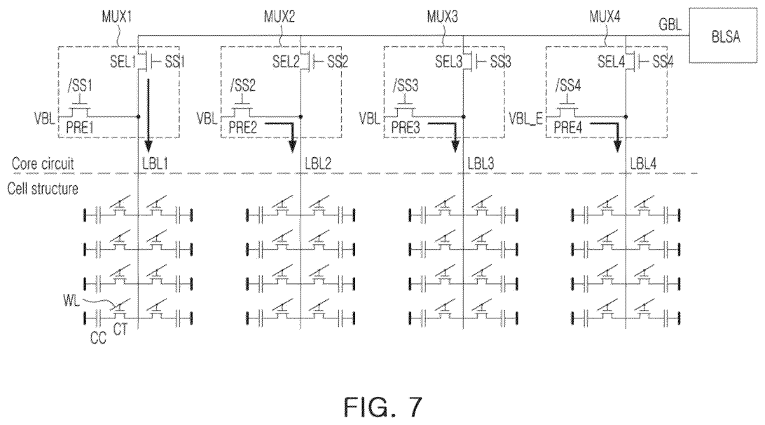

FIG. 7 is a circuit diagram illustrating a memory device according to an example embodiment.

FIG. 7 illustrates circuits associated with a global bitline GBL. Referring to FIG. 7, a global bitline GBL may correspond to a plurality of local bitlines LBL (LBL1, LBL2, LBL3, and LBL4). Each of the plurality of local bitlines LBL may be selectively connected to the global bitline GBL or to a precharge power line VBL through multiplexer circuits MUX1, MUX2, MUX3, MUX4.

The plurality of local bitlines LBL may be connected to a plurality of memory cells each including a cell capacitor CC and a cell transistor CT, respectively. The global bitline GBL may be connected to a bitline sense amplifier BLSA, which may be provided in a bitline sense amplifier block BLSAB. The bitline sense amplifier BLSA may be further connected to a complementary global bitline paired with the global bitline GBL.

The first multiplexer circuit MUX1 may include a first select transistor SEL1 and a first precharge transistor PRE1. The first select transistor SEL1 may connect the first local bitline LBL1 to the global bitline GBL in response to a logic high state of the first select signal SS1. The first precharge transistor PRE1 may connect the first local bitline LBL1 to the precharge power line VBL in response to a logic high state of the first inverted select signal/SS1, which is an inverted signal of the first select signal SS1.

The second to fourth multiplexer circuits MUX2-MUX4 may also include select transistors SEL2, SEL3, and SEL4 and precharge transistors PRE2, PRE3, and PRE4, similarly to the first multiplexer circuit MUX1.

The multiplexer circuits MUX1, MUX2, MUX3, and MUX4 may select a local bitline among a plurality of local bitlines LBL1, LBL2, LBL3, and LBL4 to be electrically connected to the global bitline GBL.

For example, to access a memory cell MC connected to the first local bitline LBL1, the first local bitline LBL1 may be connected to the global bitline GBL, and the second to fourth local bitlines LBL2, LBL3, and LBL4 may be disconnected from the global bitline GBL.

The first select signal SS1 may be in a logic high state such that the first local bitline LBL1 may be connected to the global bitline GBL, and the second to fourth select signals SS2, SS3, and SS4 may be in a logic low state such that the second to fourth local bitlines LBL2, LBL3, and LBL4 may be disconnected from the global bitline GBL. The second to fourth local bitlines LBL2, LBL3, and LBL4 may be connected to the precharge power line VBL in response to the second to fourth inverted select signals/SS2,/SS3, and/SS4. That is, while the first local bitline LBL1 is connected to the global bitline GBL, the second to fourth local bitlines LBL2, LBL3, and LBL4 may be precharged.

In an example embodiment, the precharge power line VBL may include a plurality of precharge power lines for precharging different local bitlines. For example, the precharge power line VBL may include first and second precharge power lines. The first and third precharge transistors PRE1 and PRE3 included in the first and third multiplexers MUX1 and MUX3 may be connected to the first precharge power line, and the second and fourth precharge transistors PRE2 and PRE4 included in the second and fourth multiplexers MUX2 and MUX4 may be connected to the second precharge power line. That is, among the local bitlines, even-numbered local bitlines and odd-numbered local bitlines may be precharged by different precharge power lines.

The number of precharge power lines is not limited to any particular example, and the precharge power line VBL may include one precharge power line or three or more precharge power lines.

According to an example embodiment, the memory device may discharge the local bitlines by lowering a voltage level of the precharge power line while the local bitlines are connected to the precharge power line, and may perform a body refresh operation of the memory cells connected to the local bitlines.

During normal operation, the voltage level of the precharge power line VBL may be an intermediate level VINTA/2 between the first power voltage level VINTA and the second power voltage level VSS. The intermediate level VINTA/2 may also be referred to as a precharge voltage level.

According to an example embodiment, to perform a body refresh operation on the memory cells connected to the target local bitline, the memory device may connect the target local bitline to the precharge power line VBL and may lower the precharge voltage level to a level lower than a level of the body voltage level of the memory cells, for example, the second power voltage level VSS.

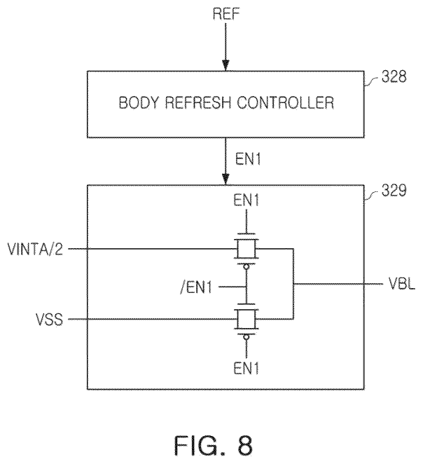

FIG. 8 is a diagram illustrating a body refresh circuit according to an example embodiment.

The body refresh circuit may include a body refresh control circuit 328 and a precharge voltage select circuit 329. The body refresh control circuit 328 may correspond to the body refresh control circuit 328 described with reference to FIG. 4. The precharge voltage select circuit 329 may be included in a sense amplifier, such as the sense amplifier 342 as described with reference to FIG. 4.

In an example embodiment, one or more precharge voltage select circuits 329 may be provided per bank of the memory device. For example, the sense amplifier 342 may include two precharge voltage select circuits 329, one of which is configured to provide a first precharge voltage to odd-numbered local bitlines and the other of which is configured to provide a second precharge voltage to even-numbered local bitlines.

The body refresh control circuit 328 may provide an enable signal EN1 to the selected precharge voltage select circuit 329 based on a refresh control signal REF received from the control logic circuit 310 described with reference to FIG. 4.

In an example embodiment, the control logic circuit 310 may periodically generate a refresh control signal REF in response to a request from a memory controller or based on an internal timer, and may provide the refresh control circuit REF to the data refresh control circuit 323 or the body refresh control circuit 328.

In an example embodiment, the body refresh control circuit 328 may select memory cell blocks in sequence such that a body refresh operation may be performed periodically on the entirety of memory cell blocks. In an example embodiment, the body refresh control circuit 328 may select a vulnerable block in which a floating body effect is determined to occur significantly and may perform the body refresh operation.

When the body refresh operation and the data refresh operation are performed simultaneously, the body refresh control circuit 328 may select one or more memory cell blocks on which the body refresh operation is to be performed other than the memory cell blocks on which the data refresh operation is to be performed.

The precharge voltage select circuit 329 may obtain the voltage of intermediate level VINTA/2 from the voltage generator 331 as described with reference to FIG. 4. In the example in FIG. 8, the precharge voltage select circuit 329 may provide the voltage of intermediate level VINTA/2 as the precharge voltage VBL when the enable signal EN1 is in a logic low state. The precharge voltage select circuit 329 may provide the voltage of the second power voltage level VSS as the precharge voltage VBL when the enable signal EN1 is in a logic high state. That is, the precharge voltage select circuit 329 may output the voltage of intermediate level VINTA/2 during a normal operation, and may output the voltage of the second power voltage level VSS during the body refresh operation.

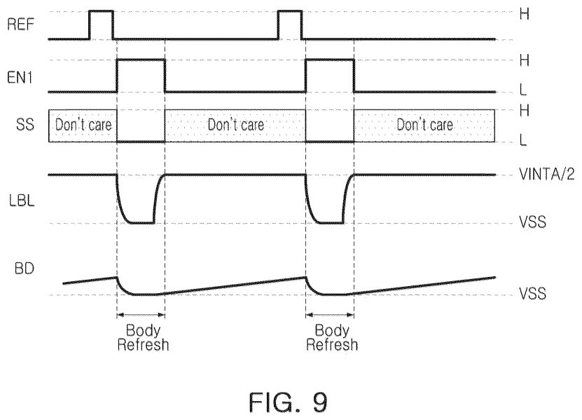

FIG. 9 is a signal diagram illustrating a body refresh operation according to an example embodiment.

FIG. 9 illustrates a refresh control signal REF, an enable signal EN1, a select signal SS, a voltage and a body voltage BD of local bitline LBL when a body refresh operation is performed on memory cells connected to one of the local bitlines LBL as described with reference to FIG. 7.

Referring to FIG. 9, a body refresh control circuit 328 may enable the body refresh operation of the local bitline LBL by outputting enable signal EN1 in a logic high H state for a predetermined period in response to a logic high H state of refresh control signal REF.

At least during the period in which the enable signal EN1 is in a logic high state, a select signal SS of the multiplexer of the local bitline LBL may be disabled. That is, while the body refresh operation is performed, the local bitline LBL may not be connected to the global bitline GBL, and may be connected to the precharge power line VBL.

The precharge power line VBL may have an intermediate level VINTA/2 when the enable signal EN1 is in a logic row L state, and may have a second power voltage level VSS when the enable signal EN1 is in a logic high H state. The voltage of the local bitline LBL may decrease to the second power voltage level VSS when the enable signal EN toggles to the logic high H state, and may increase to the intermediate level VINTA/2 when the enable signal EN toggles to the logic row L state.

In a normal operation, the body voltage BD may gradually increase due to accumulation of holes in the body of the memory cells connected to the local bitline LBL. During a body refresh operation, the holes accumulated in the body may escape through the local bitline LBL having the second power voltage level VSS, and the body voltage BD may decrease to the second power voltage level VSS.

According to an example embodiment, the memory device may lower the voltage level of the local bitline LBL and may perform a body refresh operation by controlling the level of the precharge voltage VBL while the local bitline LBL is connected to the precharge power line VBL and not connected to the global bitline GBL.

According to an example embodiment, the memory device may lower the voltage level of the local bitline LBL by driving the precharge power line VBL to the second power voltage level VSS without driving the individual column control line CSL connected to the global bitline GBL to the second power voltage level VSS in sequence using the column address COL_ADDR. Accordingly, the memory device may perform a body refresh operation on the local bitlines LBL connected to the plurality of global bitlines GBL simultaneously. Accordingly, the time required for the body refresh operation may be shortened.

The memory device may perform the body refresh operation on a local bitline LBL corresponding to the global bitline GBL while simultaneously performing a data refresh operation on another local bitline LBL corresponding to the global bitline GBL. Accordingly, the total time required for the refresh operation including the body refresh operation and the data refresh operation may be reduced.

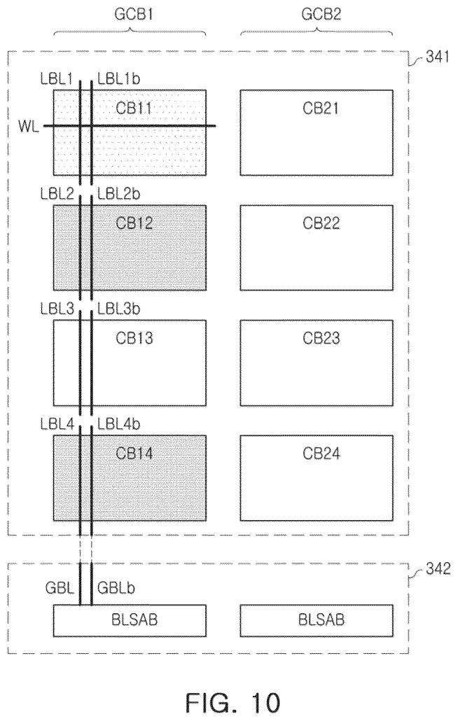

Hereinafter, an example of a region in which refresh operations may be performed simultaneously in a memory cell array will be described with reference to FIG. 10.

FIG. 10 is a diagram illustrating a memory cell array according to an example embodiment.

The memory cell array 341 and the sense amplifier 342 in FIG. 10 may correspond to the memory cell array 341 and the sense amplifier 342 described with reference to FIG. 6. In the example in FIG. 10, the memory cell blocks in which the patterns are illustrated are an example of memory cell blocks which may be refreshed simultaneously. FIG. 10 illustrates memory cell block CB11 in which a data refresh operation is performed and memory cell blocks CB12 and CB14 in which a body refresh operation is performed. Each of the data refresh operation on the memory cell block CB11, the body refresh operation on the memory cell block CB12 and the body refresh operation on the memory cell block CB14 may be performed simultaneously.

Each of the memory cell blocks CB may include a plurality of local bitlines LBL. The local bitlines LBL of the memory cell blocks CB included in a global cell block GCB may correspond to the same global bitlines GBL.

Each of the plurality of local bitlines LBL included in the memory cell block CB may be connected to a plurality of multiplexer circuits. The plurality of multiplexer circuits may perform a body refresh operation simultaneously for local bitlines LBL included in the memory cell block CB as a precharge transistor of each of the plurality of multiplexer circuits is turned on, and the precharge voltage connected to the precharge transistor decreases to the second power voltage level VSS.

Because the memory device may perform a body refresh operation without driving the bitline sense amplifier BLSA, the body refresh operation may be performed simultaneously for the local bitline LBL and the complementary local bitline LBLb connected to the same bitline sense amplifier BLSA.

According to the example illustrated in FIG. 7, among the local bitlines LBL corresponding to the global bitline GBL, odd-numbered local bitlines and even-numbered local bitlines may be connected to different precharge power lines. According to an example embodiment, the body refresh control circuit 328 may perform a body refresh operation on odd-numbered memory cell blocks or even-numbered memory cell blocks by lowering only one of the precharge power lines to the second power voltage level VSS.

However, example embodiments are not limited thereto. For example, the body refresh control circuit 328 may perform a body refresh operation on the entirety of memory cell blocks included in a global cell block simultaneously by lowering the entirety of precharge power lines to the second power voltage level VSS.

The local bitlines LBL corresponding to the global bitline GBL may be connected to three or more separate precharge power lines, or may be connected to a single precharge power line. The number of precharge power lines associated with a global bitline GBL and the number of local bitlines LBL on which a body refresh operation is performed simultaneously in a global bitline GBL may be varied according to example embodiments.

According to an example embodiment, a data refresh operation may be performed on a portion of memory cell blocks included in a global cell block while a body refresh operation may be performed on the other memory cell blocks. In the example in FIG. 10, a body refresh operation may be performed on memory cell blocks CB21 and CB41 while a data refresh operation is performed on the memory cell block CB11.

Specifically, a refresh operation may be performed on memory cells connected to the local bitlines LBL1 and the selected wordline WL while the local bitlines LBL1 and LBL1b are connected to bitline sense amplifier BLSA through the global bitlines GBL and GBLb. A body refresh operation may be performed on the local bitlines LBL2, LBL2b, LBL4, and LBL4b not connected to the global bitlines GBL and GBLb while being connected to a precharge power line.

FIG. 10 illustrates an example in which a data refresh operation and a body refresh operation are performed simultaneously in memory cell blocks included in the same global cell block GBL1. However, example embodiments are not limited thereto. For example, while a data refresh operation is performed in a memory cell block included in a first global cell block GBL1, a data refresh operation may be performed in a memory cell block included in a second global cell block GBL2. The data refresh operation and the body refresh operation may not be performed simultaneously.

In an example embodiment, the control logic circuit 310 may generate a refresh control signal REF at an interval determined in the self-refresh period, and may selectively provide the generated refresh control signal REF to the data refresh circuit 323 or the body refresh circuit 328.

For example, the interval at which the refresh control signal REF is provided to the body refresh circuit 328 may be determined according to a temperature of the memory device. The control logic circuit 310 may provide the refresh control signal REF to the body refresh circuit 328 at a shorter interval such that the body refresh operation is performed more frequently as the temperature of the memory device is higher. For example, the control logic circuit 310 may provide the refresh control signal REF to the body refresh circuit 328 once out of ten times at the first temperature, and may provide the other refresh control signal REF to the data refresh circuit 323. The control logic circuit 310 may provide a refresh control signal REF out of five times to the body refresh circuit 328 at a second temperature higher than the first temperature.

In an example embodiment, the body refresh circuit 328 may select a memory cell block on which a body refresh operation is to be performed in response to the refresh control signal REF. For example, the body refresh circuit 328 may perform a body refresh operation by selecting a vulnerable memory cell block determined to have a large floating body effect. Specifically, the body refresh circuit 328 may pre-store an address of a vulnerable memory cell block, and may refer to the address of the vulnerable memory cell block in response to the refresh control signal REF, and may perform a body refresh operation on the memory cell block.

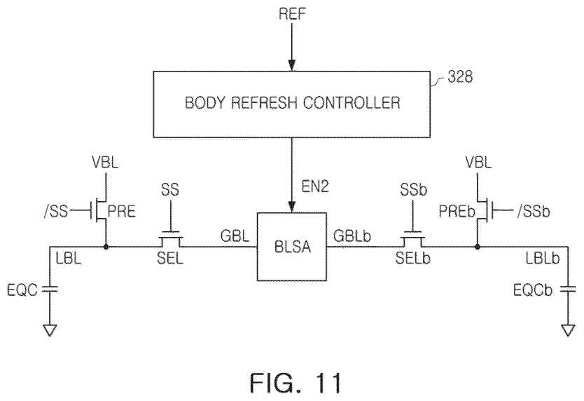

A body refresh operation according to an example embodiment is described with reference to FIGS. 8 to 10. However, the body refresh operation according to an example embodiment is not limited thereto. For example, instead of lowering the power voltage level of the precharge power line, the refresh circuit may perform the body refresh operation by lowering the bitline voltage to the second power voltage level VSS using the sense and amplification operation of the bitline sense amplifier BLSA. Hereinafter, a body refresh operation according to an example embodiment will be described with reference to FIGS. 11 to 15.

FIG. 11 is a circuit diagram illustrating a body refresh circuit according to an example embodiment.

Referring to FIG. 11, the body refresh circuit may include a body refresh controller (i.e., a body refresh control circuit) 328 and a bitline sense amplifier BLSA. The bitline sense amplifier BLSA may be connected to a global bitline pair GBL and GBLb.

Circuits connected to the global bitline GBL and the complementary global bitline GBLb may have the same structure as described with reference to FIG. 7. In the example in FIG. 11, a local bitline LBL among a plurality of local bitlines corresponding to the global bitline GBL, and a select transistor SEL and a precharge transistor PRE corresponding to the local bitline LBL are illustrated. Memory cells connected to the local bitline LBL are illustrated with an equivalent capacitance EQC.

Similarly, a complementary local bitline LBLb among a plurality of local bitlines corresponding to the complementary global bitline GBLb, and a complementary select transistor SELb and a complementary precharge transistor PREb corresponding to the complementary local bitline LBLb are illustrated. Memory cells connected to the complementary local bitline LBLb are illustrated with complementary equivalent capacitance EQCb.

According to an example embodiment, the body refresh control circuit 328 may discharge the local bitline LBL to a second power voltage level VSS by differentiating turn-on timings of the select transistors SEL and SELb and sensing and amplifying a difference in voltage levels between the local bitline LBL and the complementary local bitline LBLb due to a difference in the turn-on timings. Because the voltage level of the local bitline LBL is discharged to the second power voltage level VSS, a body refresh operation may be performed on the memory cells connected to the local bitline LBL.

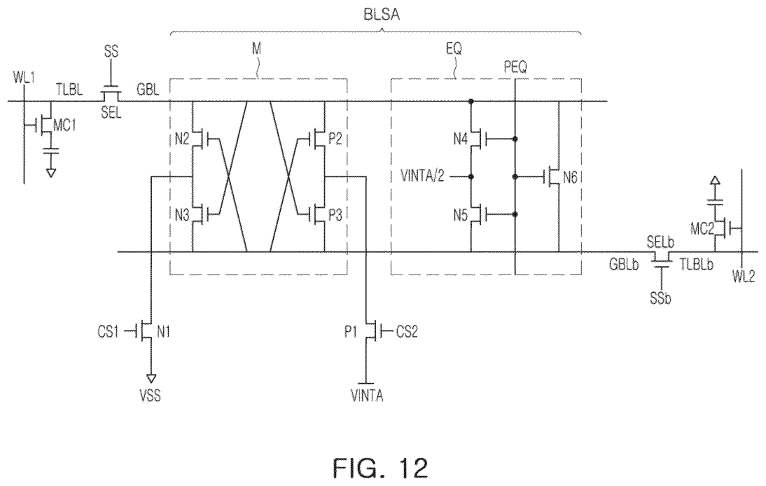

FIG. 12 is a diagram illustrating a bitline sense amplifier circuit according to an example embodiment.

Referring to FIG. 12, the target local bitline pair LBL and LBLb may be connected to the bitline sense amplifier BLSA through the select transistors SEL, SELb.

The bitline sense amplifier BLSA may include a main circuit M for sensing and amplifying a difference in voltage levels between the global bitline pair GBL and GBLb, and an equalization circuit EQ for precharging the global bitline pair GBL and GBLb to have equal voltage levels.

The main circuit M may include first to third NMOS transistors N1, N2, and N3, and first to third PMOS transistors P1, P2, and P3. The first to third NMOS transistors N1, N2, and N3 may discharge a bitline having a lower voltage level among the global bitline pair GBL and GBLb to a second power voltage level VSS. The first to third PMOS transistors P1, P2, and P3 may charge the bitline having a higher voltage level among the global bitline pair GBL and GBLb to the first power voltage level VINTA.

A drain of the first NMOS transistor N1 may be connected to sources of the second and third NMOS transistors N2 and N3, a source of the first NMOS transistor N1 may be connected to ground, and a gate of the first NMOS transistor N1 may be connected to the first control signal CS1. A drain of the second NMOS transistor N2 may be connected to the global bitline GBL, and a gate may be connected to the complementary global bitline GBLb. A drain of the third NMOS transistor N3 may be connected to the complementary global bitline GBLb, and a gate may be connected to the global bitline GBL.

A drain of the first PMOS transistor P1 may be connected to sources of the second and third PMOS transistors P2 and P3, a source of the first PMOS transistor P1 may be connected to the second level power voltage VSS, and a gate of the first PMOS transistor P1 may be connected to the second control signal CS2. A drain of the second PMOS transistor P2 may be connected to a global bitline GBL, and a gate may be connected to the complementary global bitline GBLb. A drain of the third PMOS transistor P3 may be connected to the complementary global bitline GBLb, and a gate may be connected to the global bitline GBL.

The equalization circuit EQ may include the fourth to sixth NMOS transistors N4, N5, and N6. The equalization circuit EQ may apply an intermediate level voltage of VINTA/2 to the global bitline pair GBL and GBLb in response to a logic high state of an equalization signal PEQ.

The gates of the fourth to sixth NMOS transistors N4, N5, and N6 may be connected to the equalization signal PEQ. The drain of the fourth NMOS transistor N4 and the drain of the sixth NMOS transistor N6 may be connected to the global bitline GBL, and the source of the fifth NMOS transistor N5 and the source of the sixth NMOS transistor N6 may be connected to the complementary global bitline GBLb. The source of the fourth NMOS transistor N4 and the drain of the fifth NMOS transistor N5 may be connected to a voltage of intermediate level VINTA/2.

According to an example embodiment, the body refresh control circuit 328 may discharge the local bitline LBL by differentiating the turn-on timings of the select transistor SEL and the complementary select transistor SELb.

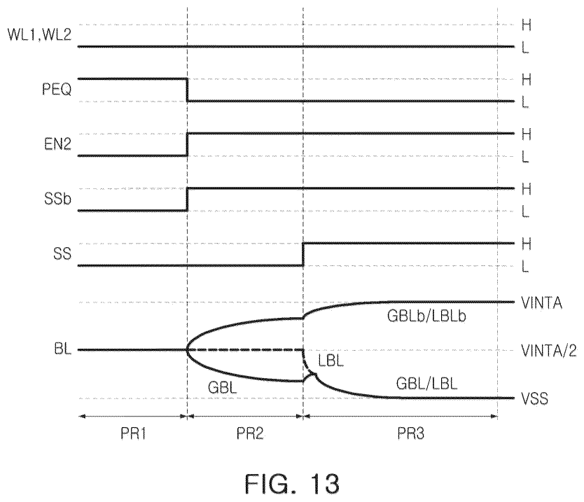

FIG. 13 is a signal diagram illustrating a body refresh operation according to an example embodiment.

FIG. 13 illustrates voltage levels of wordlines WL1 and WL2, refresh control signal REF, select signal SS, complementary select signal SSb, precharge control signal PEQ, target local bitline pair LBL, LBLb, global bitline pair GBL and GBLb when a body refresh operation is performed on memory cells connected to a local bitline LBL as described with reference to FIG. 11.

Referring to FIG. 13, the body refresh control circuit 328 may enable a body refresh operation of the local bitline LBL by outputting an enable signal EN2 of a logic high H state at a predetermined interval in response to the refresh control signal REF.

While the body refresh operation of the local bitline LBL is enabled, the wordlines WL1 and WL2 connected to the memory cells MC1 and MC2 connected to the target local bitline pair LBL and LBLb may maintain a logic row L state in which the memory cells MC1 and MC2 are turned off. For example, the wordlines WL1 and WL2 may maintain a voltage level below the second power voltage level VSS. Because the memory cells MC1 and MC2 may be turned off while the body refresh operation is performed, loss of data of the memory cells MC1 and MC2 may be prevented.

In the first period PR1 before the body refresh operation is performed, the equalization signal PEQ may have a logic high H state, and the global bitline pair GBL and GBLb may be precharged to an intermediate level VINTA/2.

In the first period PR1, the select signal SS and the complementary select signal SSb may have a logic row L state. Accordingly, the select transistor SEL and the complementary select transistor SELb may be turned off. Conversely, the precharge transistor PRE and the complementary precharge transistor PREb may be turned on. The local bitline pair LBL, LBLb may be precharged to an intermediate level VINTA/2.

In the second period PR2 after the first period PR1, the complementary select signal SSb may be toggled to a logic high H state. In the second period PR2, the complementary select transistor SELb may be turned on, and the select transistor SEL may maintain a turned-off state. The equalization signal PEQ may be toggled to a logic row L state. The bitline sense amplifier BLSA may terminate the precharge operation of the global bitline pair GBL and GBLb, and may sense and amplify a difference in voltage levels between the global bitline pair GBL and GBLb.

Referring to FIGS. 12 and 13 together, the complementary global bitline GBLb may be connected to the complementary local bitline LBLb and the complementary equivalent capacitance EQCb as the complementary select transistor SELb is turned on. The global bitline GBL may be connected to none of local bitlines including the local bitline LBL. Accordingly, loading capacitance of the global bitline GBL may be lower than loading capacitance of the complementary global bitline GBLb.

A voltage of the global bitline pair GBL and GBLb, precharged to the intermediate level VINTA/2 before the second period PR2, may be self-discharged. Due to a difference in the loading capacitance, the voltage of the global bitline GBL may be discharged more swiftly than the voltage of the complementary global bitline GBLb, and the voltage of the global bitline GBL may become lower than the voltage of the complementary global bitline GBLb. The bitline sense amplifier BLSA may sense and amplify a difference in voltage levels between the global bitline pair GBL and GBLb, thereby discharging the global bitline GBL to the second power voltage level VSS and charging the complementary global bitline GBLb to the first power voltage level VINTA.

In the third period PR3 after the second period PR2, the select signal SS may be toggled to the logic high H state. The select transistor SEL may be turned on in the third period PR3.

In the third period PR3, the local bitline LBL may be charged to the intermediate level VINTA/2, such that the voltage level of the global bitline GBL may slightly increase when the local bitline LBL and the global bitline GBL are electrically connected to each other. However, the voltage level of the global bitline GBL may still be less than the intermediate level VINTA/2, and the voltage levels of the complementary global bitline GBLb and the complementary local bitline LBLb may be higher than the intermediate level VINTA/2.

By operation of the bitline sense amplifier BLSA, the voltage levels of the complementary local bitline LBLb and the complementary global bitline GBLb may increase to the first power voltage level VINTA, and the voltage levels of the local bitline LBL and the global bitline GBL may decrease to the second power voltage level VSS.

Accordingly, by differentiating turn-on timings of the select transistor SEL connecting the local bitline LBL to the global bitline GBL, and the complementary select transistor SELb connecting the complementary local bitline LBLb to the complementary global bitline GBLb, and operating the bitline sense amplifier BLSA, the local bitline LBL may be discharged to the second power voltage level VSS.

As described with reference to FIG. 9, when the local bitline LBL is discharged to the second power voltage level VSS, the accumulated holes in the body of the memory cells connected to the local bitline LBL may be discharged through the local bitline LBL, and the voltage level of the body may be discharged to the second power voltage level VSS.

In FIGS. 11 to 13, an example embodiment in which a body refresh operation is performed on a local bitline connected to the global bitline GBL is illustrated. However, example embodiments are not limited thereto. Specifically, a body refresh operation may be performed simultaneously on a plurality of local bitlines connected to the global bitline GBL.

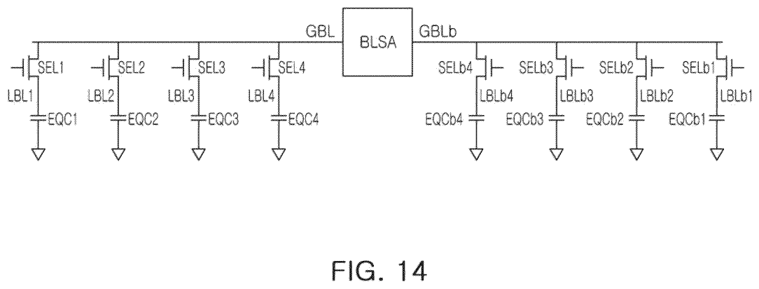

FIG. 14 is a circuit diagram illustrating a memory device according to an example embodiment.

FIG. 14 illustrates circuits connected to the bitline sense amplifier BLSA, the global bitline pair GBL and GBLb, the plurality of local bitlines LBL1, LBL2, LBL3, and LBL4, and the plurality of complementary local bitlines LBLb1, LBLb2, LBLb3, and LBLb4.

Circuits connected to the global bitline GBL and the complementary global bitline GBLb may have the same structure as described with reference to FIG. 7. However, memory cells connected to the plurality of local bitlines LBL1, LBL2, LBL3, and LBL4 are illustrated as a plurality of equivalent capacitances EQC1, EQC2, EQC3, and EQC4, and memory cells connected to the plurality of complementary local bitlines LBLb1, LBLb2, LBLb3, and LBLb4 are illustrated as a plurality of complementary equivalent capacitances EQCb1, EQCb2, EQCb3, and EQCb4.

According to an example embodiment, by operating the bitline sense amplifier BLSA, a body refresh operation may be performed simultaneously on memory cells connected to the plurality of local bitlines LBL1, LBL2, LBL3, and LBL4.

For example, in a first period, the body refresh control circuit 328 may precharge the global bitline pair GBL and GBLb, the plurality of local bitlines LBL1, LBL2, LBL3, and LBL4, and the plurality of complementary local bitlines LBLb1, LBLb2, LBLb3, and LBLb4 to an intermediate level VINTA/2 by turning on the precharge transistors and the precharge circuit of the bitline sense amplifier BLSA.

In a second period after the first period, the body refresh control circuit 328 may turn off the precharge circuit of the bitline sense amplifier BLSA and may turn on the entirety of the select transistors SELb1, SELb2, SELb3, and SELb4 connected to the plurality of complementary local bitlines LBLb1, LBLb2, LBLb3, and LBLb4. The plurality of equivalent capacitances EQC1, EQC2, EQC3, and EQC4 may not be connected to the global bitline GBL, and the plurality of complementary equivalent capacitances EQCb1, EQCb2, EQCb3, and EQCb4 may be connected to the complementary global bitline GBLb. As described with reference to FIG. 13, by sense and amplifying a difference in voltage levels between the global bitline pair GBL and GBLb, the bitline sense amplifier BLSA may discharge the global bitline GBL to the second power voltage level VSS and may charge the complementary global bitline to the first power voltage level VINTA.

In a third period after the second period, the refresh control circuit 328 may turn on the entirety of the select transistors SELb1, SELb2, SELb3, and SELb4 connected to the plurality of local bitlines LBL1, LBL2, LBL3, and LBL4. Due to the sensing and amplifying operation of the bitline sense amplifier BLSA, the voltage level of the plurality of local bitlines LBL1, LBL2, LBL3, and LBL4, precharged to the intermediate level VINTA/2, may be discharged to the second power voltage level VSS. Accordingly, the bodies of memory cells connected to the plurality of local bitlines LBL1, LBL2, LBL3, and LBL4 may be discharged to a second power voltage level VSS.

According to an example embodiment, a single bitline sense amplifier BLSA may perform a body refresh operation simultaneously on a plurality of local bitlines connected to a global bitline GBL. In an example embodiment, a body refresh control circuit 328 may determine the number of target local bitlines on which a body refresh operation may be performed simultaneously based on a temperature of the memory device.

According to an example embodiment, a bitline sense amplifier block BLSAB associated with a global cell block may perform a body refresh operation simultaneously on a plurality of local bitlines connected to a plurality of global bitlines. Accordingly, a body refresh operation may be performed simultaneously on multiple memory cell blocks, and the time required for a body refresh operation of a memory device may be shortened.

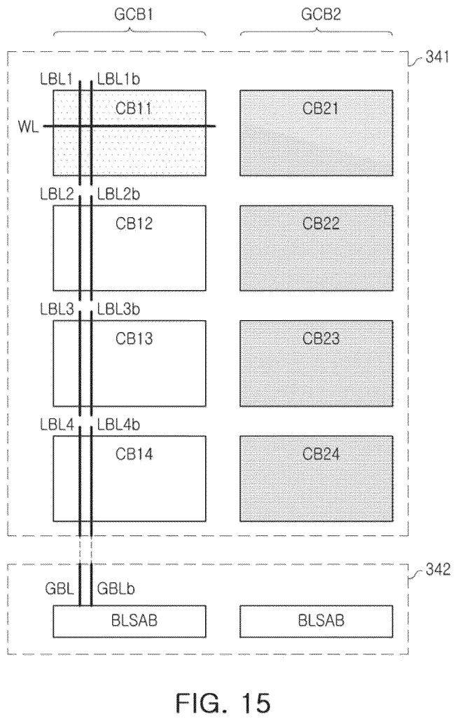

FIG. 15 is a diagram illustrating a memory cell array according to an example embodiment.

A memory cell array 341 and a sense amplifier 342 in FIG. 15 may correspond to the memory cell array 341 and the sense amplifier 342 described with reference to FIG. 6. In the example in FIG. 15, the shaded memory cell blocks indicate memory cell blocks which may be refreshed simultaneously. For example, a data refresh operation may be performed on a memory cell block CB11, and simultaneously, a body refresh operation may be performed on memory cell blocks CB12, CB22, CB32, and CB42.

A bitline sense amplifier BLSA may perform a body refresh operation simultaneously on a plurality of local bitlines connected to a global bitline GBL. Accordingly, by simultaneously driving a plurality of bitline sense amplifiers BLSA connected to a plurality of global bitlines associated with a global cell block GCB2, respectively, the body refresh operation for the memory cell blocks CB12, CB22, CB32, and CB42 may be performed simultaneously.

In the example in FIG. 15, when a global bitline GBL and a complementary global bitline GBLb connected to the bitline sense amplifier BLSA are associated with a global cell block, a body refresh operation of the first memory cells associated with the global bitline GBL and a body refresh operation of the second memory cells associated with the complementary global bitline GBLb may be performed in sequence. The body refresh operation for a memory cell block may include a body refresh operation of the first memory cells and a body refresh operation of the second memory cells, performed in sequence.

However, example embodiments are not limited thereto, and when the global bitline GBL and the complementary global bitline GBLb connected to the bitline sense amplifier BLSA are associated with different global cell blocks, the body refresh operation may be performed simultaneously on the memory cells included in the memory cell block.

As described with reference to FIG. 10, the interval at which the body refresh operation is performed may be varied depending on the temperature of the memory device. For example, the control logic circuit 310 described with reference to FIG. 4 may periodically generate a refresh control signal, and may provide the refresh control signal to the body refresh control circuit 328 at a shorter interval as the temperature of the memory device increases.

According to an example embodiment, the number of memory cell blocks on which the body refresh operation may be performed simultaneously may be varied. In an example embodiment, the body refresh control circuit 328 may further determine the number of target memory cell blocks on which the body refresh operation may be performed simultaneously based on the temperature.

According to an example embodiment, the memory device may efficiently perform a wide range of refresh operations using the hierarchical structure of the global bitline GBL and the local bitline LBL. For example, instead of performing the body refresh operation in sequence on each of the selected global bitlines GBL based on the column address COL_ADDR, the memory device may perform the body refresh operation by unit of a memory cell block. Also, the body refresh operation may be performed simultaneously on the plurality of memory cell blocks included in a global cell block. Accordingly, the time required for the body refresh operation of the memory device may be reduced, and the dynamic refresh characteristic may be improved.

According to the aforementioned example embodiments, the memory device may easily remove holes accumulated in the body of a cell transistor by controlling the precharge voltage level in a structure in which bitlines are hierarchized into global bitlines and local bitlines while the local bitlines are connected to a precharge power line.

Also, the memory device may lower the voltage level of a target bitline and may easily remove holes accumulated in the body of a cell transistor by controlling the connection timings of the global bitline and the local bitline, and the complementary global bitline and complementary local bitline in a structure in which the global bitline and the complementary global bitline are connected to a bitline sense amplifier.

Also, the memory device may perform a body refresh operation on memory cells connected to multiple global bitlines simultaneously, and may perform a body refresh operation simultaneously with a data refresh operation. Accordingly, the time required for the body refresh operation may be reduced.

While aspects of example embodiments have been illustrated and described above, it will be apparent to those skilled in the art that modifications and variations could be made without departing from the scope of the present disclosure as defined by the appended claims.

What is claimed is:

1. A memory device, comprising:
a plurality of wordlines;
a plurality of local bitlines;
a plurality of memory cells connected to the plurality of wordlines and the plurality of local bitlines, wherein a first memory cell of the plurality of memory cells is connected to a wordline among the plurality of wordlines and a local bitline among the plurality of local bitlines, wherein the first memory cell comprises a cell transistor and a cell capacitor, and wherein the cell transistor comprises a first impurity region connected to the local bitline, a second impurity region connected to the cell capacitor, a body region between the first impurity region and the second impurity region, and a gate structure connected to the wordline on a surface of the body region;
a global bitline;
a plurality of multiplexers comprising a first multiplexer, the first multiplexer configured to selectively connect the local bitline to the global bitline or to a precharge power line;
a bitline sense amplifier connected to the global bitline; and
a body refresh control circuit configured to control a body refresh operation of controlling the plurality of multiplexers to connect at least one target local bitline among the plurality of local bitlines to the precharge power line, and control a voltage level of the precharge power line connected to the at least one target local bitline to a first level lower than a voltage level of the body region.

2. The memory device of claim 1, wherein the first level is a ground level.

3. The memory device of claim 2, wherein the memory device further comprises a precharge voltage select circuit configured to selectively provide, to the precharge power line, an intermediate voltage level between the ground level and an internal power voltage higher than the ground level, or the ground level, according to control of the body refresh control circuit.

4. The memory device of claim 1, wherein the precharge power line comprises a first precharge power line and a second precharge power line, and
wherein first multiplexers among the plurality of multiplexers are connected to the first precharge power line, and second multiplexers among the plurality of multiplexers are connected to the second precharge power line.

5. The memory device of claim 1, wherein the memory device further comprises a data refresh control circuit configured to control the plurality of multiplexers to connect a selected local bitline among the plurality of local bitlines to the global bitline, and to refresh data stored in one of the plurality of memory cells connected to the selected local bitline using the bitline sense amplifier.

6. The memory device of claim 5, wherein the memory device further comprises a control logic circuit configured to provide a refresh control signal to the body refresh control circuit or the data refresh control circuit according to an external refresh command or an internal timer.

7. The memory device of claim 6, wherein the control logic circuit is further configured to selectively provide the refresh control signal to the body refresh control circuit or the data refresh control circuit according to the external refresh command.

8. The memory device of claim 6, wherein the selected local bitline and the at least one target local bitline are different local bitlines, and
wherein the control logic circuit is further configured to simultaneously provide the refresh control signal to the body refresh control circuit and the data refresh control circuit according to the external refresh command.

9. The memory device of claim 1, wherein each of the plurality of multiplexers comprises:
a select transistor connected between one of the plurality of local bitlines and the global bitline, and configured to turn on according to a select signal; and
a precharge transistor connected between the one local bitline and the precharge power line, and configured to turn on according to an inverted signal of the select signal.

10. The memory device of claim 1, wherein the cell transistor has a gate all around (GAA) structure or a vertical channel transistor (VCT).

11. A memory device, comprising:
a plurality of first wordlines;
a plurality of second wordlines;
a plurality of local bitlines;
a plurality of complementary local bitlines;
a plurality of first memory cells connected to the plurality of first wordlines and the plurality of local bitlines;
a plurality of second memory cells connected to the plurality of second wordlines and the plurality of complementary local bitlines;
a global bitline;
a complementary global bitline;
a plurality of first multiplexers configured to selectively connect each of the plurality of local bitlines to the global bitline or a precharge power line;
a plurality of second multiplexers configured to selectively connect each of the plurality of complementary local bitlines to the complementary global bitline or the precharge power line;
a bitline sense amplifier connected to the global bitline and the complementary global bitline; and
a body refresh control circuit configured to:
control the global bitline and the complementary global bitline to be precharged, and the plurality of local bitlines and the plurality of complementary local bitlines to be connected to the precharge power line, in a first period;
control at least one complementary target local bitline selected from among the plurality of complementary local bitlines to be connected to the complementary global bitline, in a second period subsequent to the first period;
control at least one target local bitline selected from among the plurality of local bitlines to be connected to the global bitline, in a third period subsequent the second period; and
control a body refresh operation in which the bitline sense amplifier senses and amplifies a difference in voltage levels between the global bitline and the complementary global bitline in the second period and the third period.

12. The memory device of claim 11, wherein the body refresh control circuit is further configured to turn off first target memory cells connected to at least one target local bitline and second target memory cells connected to at least one complementary target local bitline in the second period and the third period.

13. The memory device of claim 11, wherein the body refresh control circuit is further configured to control a voltage having a level equal to or lower than a ground level to the plurality of first wordlines and the plurality of second wordlines in the second period and the third period.

14. The memory device of claim 11, wherein the memory device further comprises a control logic circuit configured to determine an interval at which a refresh control signal is provided to the body refresh control circuit based on a temperature of the memory device.

15. The memory device of claim 11, wherein each of the plurality of first memory cells and each of the plurality of second memory cells comprises a cell transistor and a cell capacitor, and the cell transistor of each of the plurality of first memory cells and each of the plurality of second memory cells comprises a first impurity region connected to the one local bitline or the one complementary local bitline, a second impurity region connected to the cell capacitor, a body region between the first impurity region and the second impurity region, and a gate structure providing a wordline on a surface of the body region.

16. A memory device, comprising:
a plurality of memory cell blocks, each of the plurality of memory cell blocks comprising a plurality of memory cells connected to a plurality of wordlines and a plurality of local bitlines;
a plurality of global bitlines, each of the plurality of global bitlines corresponding to two or more local bitlines among the plurality of local bitlines;
a plurality of multiplexers configured to selectively connect each of the plurality of local bitlines to a corresponding global bitline or a precharge power line;
a plurality of bitline sense amplifiers, each of the plurality of bitline sense amplifiers connected to two global bitlines among the plurality of global bitlines, and configured to sense and amplify a difference in voltage levels between the two global bitlines; and
a body refresh control circuit configured to control the plurality of multiplexers to connect a plurality of first local bitlines provided in at least one memory cell block among the plurality of memory cell blocks to the precharge power line, and to control perform a body refresh operation comprising lowering a level of the precharge power line.

17. The memory device of claim 16, wherein the body refresh control circuit is further configured to pre-store an address of a specific memory cell block among the plurality of memory cell blocks and to select the at least one memory cell block by referring to the address.

18. The memory device of claim 16, wherein the body refresh control circuit is further configured to control an interval at which the body refresh operation is performed on the plurality of memory cell blocks based on a temperature of the memory device.

19. The memory device of claim 16, wherein the memory device further comprises a data refresh control circuit configured to control the plurality of multiplexers to connect a plurality of second local bitlines provided in a selected memory cell block among the plurality of memory cell blocks to the plurality of global bitlines, and to control a data refresh operation on memory cells commonly connected to a same wordline among the memory cells connected to the plurality of second local bitlines.

20. The memory device of claim 19, further comprising a control logic circuit configured to:
provide a refresh control signal to the body refresh control circuit and the data refresh control circuit according to an external refresh command or an internal timer; and
control the body refresh operation and the data refresh operation to be performed simultaneously.
